(19) United States
(12) Patent Application Publication
(10) Pub. No.: US 2010/0126560 A1
(43) Pub. Date: May 27, 2010

(54) PHOTOVOLTAIC MODULE COMPRISING A POLYMER FILM AND PROCESS FOR MANUFACTURING SUCH A MODULE

(75) Inventors: Hubert Lauvray, Paris (FR); Klaus Bamberg, Lyon (FR)

Correspondence Address: OLIFF & BERRIDGE, PLC, P.O. BOX 320850, ALEXANDRIA, VA, 22320-4850, US

(73) Assignee: APOLLON SOLAR, Paris (FR)

(21) Appl. No.: 12/451,921

(22) PCT Filed: Jun. 3, 2008
(86) PCT No.: PCT/FR2008/000752

§ 371 Date: Dec. 7, 2009

(30) Foreign Application Priority Data
Jun. 21, 2007 (FR) 0704443

(51) Int. Cl. H01L 31/048; H01L 31/18

(52) U.S. Cl. 136/251; 438/67; 257/E31.11; 977/773

(57) ABSTRACT

A photovoltaic module comprising front and back plates each comprising inner and outer faces, a plurality of photovoltaic cells arranged side by side between the front and back plates and each comprising an antireflection layer, and a peripheral seal arranged between the front and back plates around the photovoltaic cells. The part of the inner face of the front plate delineated by the seal is coated with a polymer film presenting a refractive index comprised between that of the front plate and that of the antireflection layers of the photovoltaic cells, said film being in contact with the photovoltaic cells.

### BACKGROUND OF THE INVENTION

The invention relates to a photovoltaic module comprising:
a front plate and a back plate each comprising an inner face and an outer face,
a plurality of photovoltaic cells arranged side by side between the front and back plates and each comprising an antireflection layer,
and a peripheral seal arranged between the front and back plates around the photovoltaic cells.

The invention also relates to a process for manufacturing such a module.

### STATE OF THE ART

A photovoltaic cell is conventionally formed on a bulk silicon substrate cut into wafers having a thickness of a few hundreds microns. The substrate can be formed by single-crystal silicon, polycrystalline silicon or by another semi-conducting material. The surface of the substrate has a set of narrow electrodes, generally made of silver or aluminum, designed to drain the current to one or more main electrodes having a width ranging from one to a few millimeters, also made of silver or aluminum.

Each cell supplies a current dependent on the lighting under an electric voltage which depends of the nature of the semiconductor and which is usually about 0.45V to 0.65V for crystalline silicon. Voltages of 6V to several tens of volts usually being necessary to make electrical apparatuses work, a photovoltaic module is generally formed by a plurality of cells electrically connected in series. A module of 40 cells for example supplies about 24 volts. According to the currents required, several cells can also be placed in parallel. A generator can then be achieved by adding storage batteries, a voltage regulator and so on if desired.

To manufacture a photovoltaic module, Patent Application WO2004/095586 proposes assembling the photovoltaic cells between front and back plates, for example made of glass, and sealing said plates with a peripheral organic seal. The peripheral organic seal thereby delineates a tightly sealed inner volume in which the photovoltaic cells are arranged side by side. The assembly is then compressed and the pressure in the inner volume is reduced to a lower pressure than atmospheric pressure. Such a photovoltaic module presents a good long-term tightness and is simpler and less costly to manufacture than previous photovoltaic modules using a tin, lead and zinc base solder paste. However, this photovoltaic module configuration requires deposition of one or more antireflection layers on both faces of the front plate in order to remedy the optical discontinuity existing between the front plate and the antireflection layer of each photovoltaic cell receiving light from outside the cell. Furthermore, such a module, sealed by means of a peripheral organic seal, is not sufficiently shock-resistant.

### OBJECT OF THE INVENTION

The object of the invention is to remedy these shortcomings, and in particular to propose a photovoltaic module presenting an improved shock-resistance and providing an optical continuity from the front plate up to the photovoltaic cells, and more particularly up to the antireflection layers of said cells.

A further object of the invention is to propose a process for manufacturing such a photovoltaic module that is easy to implement and does not generate additional costs.

According to the invention, this object is achieved by the appended claims.

### BRIEF DESCRIPTION OF THE DRAWINGS

Other advantages and features of the invention will become more clearly apparent from the following description of particular embodiments of the invention given for non-restrictive example purposes only and represented in the accompanying drawings in which:

FIG. 1 schematically represents, in cross-section, a particular embodiment of a photovoltaic module according to the invention.

FIG. 2 illustrates a particular embodiment of manufacturing of the module according to FIG. 1.

FIG. 3 schematically represents, in cross-section, an alternative embodiment of the photovoltaic module according to FIG. 1.

### DESCRIPTION OF PARTICULAR EMBODIMENTS

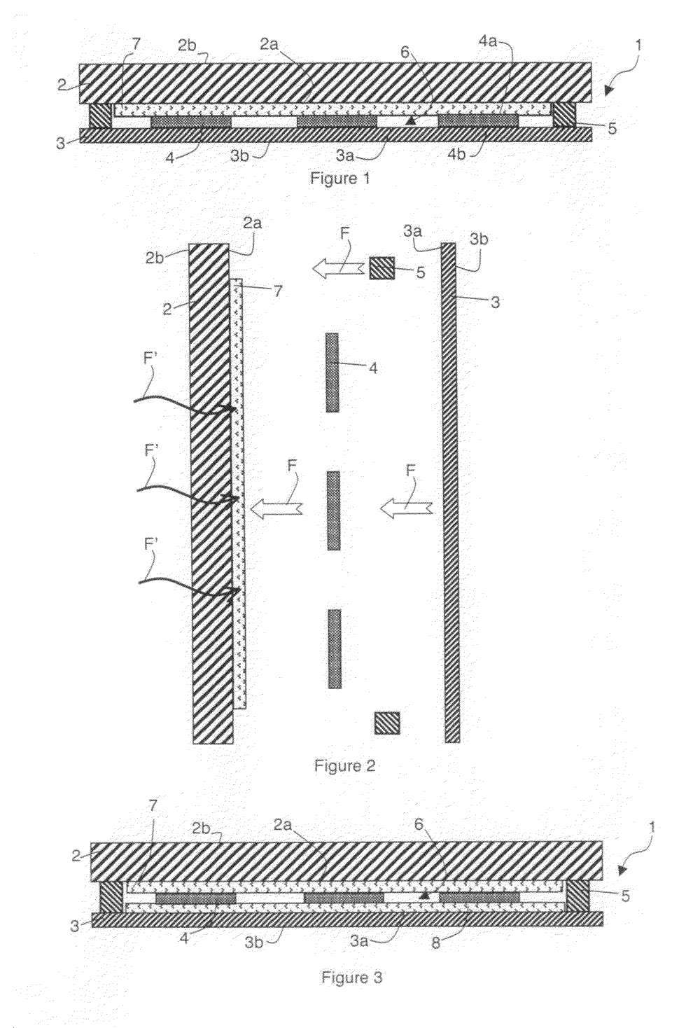

According to a particular embodiment represented in FIG. 1, a photovoltaic module 1 comprises a front plate 2 and back plate 3 each provided with an inner face 2a, 3a and an outer face 2b, 3b. Front plate 2 is advantageously made of glass and back plate 3 can be made of glass or metal foil.

A plurality of photovoltaic cells 4 are arranged side by side and between front plate 2 and back plate 3. They further each comprise an antireflection layer (not shown in FIG. 1) with a preset refractive index. Three photovoltaic cells 4 are thus represented in FIG. 1. In conventional manner, module 1 further comprises corresponding electrical interconnection conductors associated with said cells (not shown in FIG. 1). Said conductors are in general arranged salient from one of the two, front 4a or back 4b, faces of photo-voltaic cells 4.

A preferably organic peripheral seal 5 is further positioned between front plate 2 and back plate 3 around the assembly formed by the plurality of photovoltaic cells 4. Said seal 5 thus delineates a sealed volume 6 in which photovoltaic cells 4 are located. Furthermore, as in Patent Application WO2004/095586, the pressure in inner volume 6 can advantageously be maintained at a lower pressure than atmospheric pressure.

Finally, the photovoltaic module comprises a polymer film 7 coming into contact with both photovoltaic cells 4 and front plate 2. What is meant by polymer film is a film comprising at least one or more polymers. More particularly, polymer film 7 is arranged on a part of the inner face of the front plate corresponding to the part delineated by seal 5, i.e. the part of inner face 2a of front plate 2 forming the sealed inner volume 6 with seal 5 and the corresponding part of inner face 3a of back plate 3. In FIG. 1, seal 5 is in direct contact with inner face 2a of front plate 2 and with inner face 3a of back plate 3.

The respective thicknesses of front plate 2 and back plate 3 are generally comprised between 3 mm and 4 mm for front plate 2 and between 0.1 mm and 4 mm for back plate 3. The thickness of seal 5 depends on the thickness of photovoltaic cells 4, but is generally comprised between 0.2 mm and 1 mm and more typically 0.7 mm. Polymer film 7 preferably has a thickness of about 10 μm if the electrical interconnection conductors are arranged on back faces 4b of photovoltaic cells 4, and about the thickness of said conductors, typically 200 μm, if the latter are arranged on front faces 4a and back faces 4b of cells 4.

Polymer film 7 can be formed by one or more thin layers comprising a polymer matrix. The polymer matrix is for example formed by at least one polyacrylic polymer or by at least one polyurethane polymer and advantageously does not comprise any solvent. For example purposes, the polymer matrix can be a mixture of polyacrylate polymers or copolymers containing at least 50% of an acrylic monomer of general formula CR₁R₂ in which the radical R₁ is hydrogen or a methyl group and the radical R₂ is hydrogen or a saturated hydrocarbonaceous chain comprising between 1 and 30 atoms of carbon. The saturated hydrocarbonaceous chain can be branched or not.

Polymer film 7 further presents a refractive index comprised between that of front plate 2 and that of the antireflection layers of photovoltaic cells 4. The structure and/or composition of polymer film 7 is in fact advantageously chosen such that the polymer film presents an intermediate refractive index thereby enabling an optical continuity to be achieved in photovoltaic module 1, between front plate 2 and photovoltaic cells 4, thereby limiting optical losses. Polymer film 7 is further advantageously at least partially cross-linked.

For example, photovoltaic cells 4 can comprise a silicon nitride antireflection coating having a refractive index of about 2.3, whereas a glass plate presents a refractive index of about 1.5. In this case, the refractive index of polymer film 7 will be comprised between these two values and will advantageously be about 1.9. In another embodiment, for photovoltaic cells 4 comprising a top layer made of silicon oxide (refractive index<2), polymer film 7 will advantageously have a refractive index of about 1.76.

The refractive index of polymers does not however in general exceed the value of 1.7 or 1.8. In the case of a module comprising a glass front plate 2 and photovoltaic cells 4 with top layers of silicon oxide, such refractive index values for polymer film 7 are sufficient to ensure optical continuity in said module. In this case, the polymer film can for example be formed by a polymer matrix presenting a refractive index of about 1.7 or 1.8, for example a polyacrylic or polyurethane polymer matrix.

On the other hand, for photovoltaic cells 4 comprising silicon nitride anti-reflection coatings and in a more general manner, the refractive index of the polymer matrix can be adjusted so that polymer film 7 presents an intermediate refractive index value between that of front plate 2 and that of photovoltaic cells 4. For example, the refractive index of polymer film 7 can reach the value of 1.9 by dispersing a preset quantity of nanoparticles of at least one metal oxide in the polymer matrix of the thin layer or of at least one of the thin layers in the case of a polymer film in the form of a multilayer. Said metal oxide nanoparticles are moreover transparent to light and they advantageously present a diameter less than or equal to 10 nm. The metal oxide is for example titanium oxide or zirconium oxide.

For example purposes, titanium oxide nanoparticles are more particularly obtained from titanium oxide chelated in an organic compound such as an alkoxy-organosilane, an alcohol, a polyethylene glycol derivative or a carboxylic acid, so as to make the titanium go from its +4 valence state to its +6 valence state (more stable state). A dispersant may be used to prevent agglomeration of said nanoparticles. Furthermore, the proportion of metal oxide nanoparticles in the polymer matrix is advantageously chosen such as to find a trade-off between the required refractive index, varying linearly with the quantity of nanoparticles, and attenuation of light transmission in said polymer film, necessarily caused by the presence of said particles. For example, the proportion of titanium oxide nanoparticles in the polymer matrix can advantageously be comprised between 10% and 50% in weight and preferably between 25% and 30% in weight.

Furthermore, particles of at least one rare earth, for example a metal of the lanthanide series, can be dispersed in the polymer matrix of the thin layer or of one of the thin layers in the case of a multilayer coating. Adding such particles adjusts or modulates the incident light spectrum to the spectral response of the cell. A polymer film 7 can naturally contain both rare earth particles and metal oxide nanoparticles.

The presence of such a polymer film 7 in a photovoltaic module 1 thereby ensures an optical continuity from front plate 2 up to photovoltaic cells 4. It is then no longer necessary to deposit antireflection layers on inner face 2a of front plate 2. Furthermore, polymer film 7 improves the shock resistance of photovoltaic module 1. In the event of a mechanical shock, a glass front plate 2 will in fact break. Polymer film 7 then acts as shock absorber preventing propagation of large cracks fragmenting the glass front plate. The glass is then securedly held by polymer film 7. Furthermore, tests have shown that the presence of such a polymer film 7 did not give rise to additional outgasing which could be detrimental to the tightness of inner volume 6.

A photovoltaic module 1 such as the one represented in FIG. 1 also presents the advantage of being easier and less costly to manufacture than modules requiring the presence of antireflection layers. Polymer film 7 is in fact deposited on the part of inner face 2a of front plate 2 before assembly of the photovoltaic cells and peripheral seal is performed. Polymer film 7 deposited on front plate 2 is moreover advantageously in a state enabling it to present sufficient adhesive properties to provisionally secure the photo-voltaic cells against front plate 2 during assembly.

For example purposes, FIG. 2 illustrates a particular embodiment of photovoltaic module 1 as represented in FIG. 1. Firstly, and as represented in FIG. 2, a polymer film 7 is deposited on a part of inner face 2a of front plate 2 at a temperature of about 40° C. Said polymer film 7 further presents a dynamic viscosity, at 40° C., comprised between about 10³ PI (Poiseuille or pascal second), i.e. 10⁴ Po or P (Poise) and about 5*10³ PI, i.e. 5*10⁴ Po or P. Such a viscosity range does in fact enable film 7 to be deposited on a front plate 2 advantageously arranged in the vertical position, without the polymer running along inner face 2a of front plate 2. Then, after cooling at ambient temperature, i.e. at a temperature of about 20° C., the dynamic viscosity of said film 7 reaches a dynamic viscosity comprised between about 2*10³ PI (i.e. 2*10⁴ Po) and about 1*10⁴ PI (i.e. 1*10⁵ Po). This gives said film 7 adhesive properties enabling photovoltaic cells 4 to be securedly held against front plate 2 during assembly. More particularly, when front plate 2 is in the vertical position, such a dynamic viscosity range enables photovoltaic cells 4 to be securedly held against front plate 2 for at least 10 minutes, without any displacement movement of said photovoltaic cells 4 taking place.

As represented in FIG. 2, deposition of polymer film 7 is followed by assembly of the photovoltaic module and in particular of front plate 2 coated with polymer film 7, of photovoltaic cells 4, peripheral seal 5 and back plate 3. The different component elements of the photovoltaic module are preferably assembled according to the method described in Patent Application WO2004/095586. Thus, in FIG. 2, front plate 2 and back plate 3 are placed in the vertical position parallel to one another, polymer film 7 being arranged facing inner face 3a of back plate 3. Photovoltaic cells 4 and peripheral seal 5 are further placed between the two plates 2 and 3. Cells 4 are more particularly arranged side by side, whereas seal 5 is fitted at the periphery of said cells. Photovoltaic cells 4, seal 5 and back plate 3 are then directed towards front plate 2 (arrows F) until:
photovoltaic cells 4 come into contact with polymer film 7,
seal 5 comes into contact with inner face 2a of front plate 2,
and back plate 3 comes into contact with photovoltaic cells 4 and peripheral seal 5.

The assembly is then compressed by applying a pressure between the two plates 2 and 3. Seal 5 then delineates a tight inner volume 6 inside which photovoltaic cells 4 are located. A negative pressure is then advantageously created inside said volume 6, preferably by suction, to achieve a sufficient contact pressure to ensure the electrical conduction necessary for correct functioning of the module.

Polymer film 7 deposited on inner face 2a of the front plate can advantageously be a cross-linkable polymer film. What is meant by cross-linkable polymer film is a polymer film being in a disordered state and able to progress to a more ordered state. Thus, after the assembly step, the polymer film can be cross-linked so as to prevent the occurrence of outgasing phenomena. The method for cross-linking a polymer depends on said polymer used. However, a large number of polymers can be cross-linked by exposure to ultraviolet radiation. Polymer film 7 can thus advantageously be exposed to said radiation through front plate 2 (arrows F′ in FIG. 2) once the photovoltaic module has been assembled.

In an alternative embodiment, exposure of polymer film 7 to ultraviolet radiation can be performed during assembly. In this case, photovoltaic cells 4 are placed in contact with polymer film 7, and the parts of polymer film 7 not covered by photovoltaic cells 4 are then directly exposed to the ultraviolet radiation. Polymer film 7, equipped with photovoltaic cells 4, is thus directly exposed to ultraviolet radiation on the side where inner face 2a of front plate 2 is situated and no longer though said plate 2, so that only the parts of polymer film 7 not covered by photovoltaic cells 4 are cross-linked. Peripheral seal 5 and back plate 3 are then successively placed in contact with inner face 2a of front plate 2 before the assembly is compressed. Such an alternative embodiment improves securing of photovoltaic cells 4 against front plate 2. Subsequent cross-linking can be performed, if required, by ultraviolet radiation through front plate 2. This subsequent cross-linking can either be performed deliberately or it can take place progressively in the course of use of the photovoltaic module.

Production of polymer film 7 is perfectly integrated in the process for manufacturing the photovoltaic module such as the one described in Patent Application WO2004/095586, without generating additional manufacturing costs, replacing a delicate and costly subsequent step of deposition of anti-reflection layers.

In an alternative embodiment and as represented in FIG. 3, photovoltaic module 1 can also comprise an additional polymer film 8 covering at least a part of inner face 3a of back plate 3. In the case of a glass back plate 3, such an additional polymer film 8 deposited on said back plate 3 does in fact enable the shock resistance of said module to be improved. The material or materials constituting said film 8 can be identical or different from the material or materials deposited to form polymer film 7. It does however have to be cross-linked before the module is assembled.

It has already been proposed in the prior art to use polymer material films in producing photovoltaic cells. However, in the prior art, these polymer material films are used to seal the photovoltaic module. For example purposes, in U.S. Pat. No. 6,414,236, a photovoltaic module comprising front and back plates between which photovoltaic elements are placed is sealed by means of a polymer resin sealing material. Once production of the module has been completed, this sealing material occupies all the available space between the front and back plates. The photovoltaic elements are thus sunk in the sealing material. Such a module is produced for example by lamination. A first polymer resin film and a film designed to form the front plate are thus laminated on the front surfaces of the photovoltaic cells and a second polymer resin film and a film designed to form the back plate are laminated on the respective back surfaces of the photovoltaic cells. The laminate is then heated to 150° C. for 30 minutes. The first and second polymer resin films then form the sealing material. A large number of other documents of the prior art have a similar teaching. For example, Patent Applications WO-A-2004-038462 and EP-A-1722619 can be cited in which the polymer material used as sealing material is an ethylene/vinyl acetate copolymer, also known under the name of EVA.

According to the invention however, the polymer film used in the photovoltaic module does not have the function of performing sealing between the front and back plates. This function is in fact performed by a peripheral seal 5. This peripheral seal thereby delineates a tight inner volume 6 wherein photovoltaic cells 4 are arranged. Photovoltaic cells 4 are consequently not sunk in a particular material. Thus, in FIGS. 1 and 3, the side walls of photovoltaic cells 4 are free. Polymer film 7 performs securing of photovoltaic cells 4 against the front plate when assembly of said cells and of the seal is performed between the front and back plates. It also enables an optical continuity to be achieved between front plate 2 and photovoltaic cells 4 and a good shock resistance to be obtained. Polymer film 7 is moreover not a laminate.

1.-17. (canceled)

18. A photovoltaic module comprising:
a front plate and a back plate each comprising an inner face and an outer face,
a plurality of photovoltaic cells arranged side by side between the front plate and the back plate, each photovoltaic cell comprising an antireflection layer, and
a peripheral seal arranged between the front plate and the back plate around the photovoltaic cells,
wherein the inner face of the front plate comprises a part delineated by the seal and coated with a polymer film presenting a refractive index comprised between a refractive index of the front plate and a refractive index of the antireflection layers of the photovoltaic cells, said polymer film being in contact with the photovoltaic cells.

19. The module according to claim 18, wherein the polymer film is at least partially cross-linked.

20. The module according to claim 18, wherein the peripheral seal delineates a tight inner volume in which the photovoltaic cells are arranged and which is maintained at a lower pressure than atmospheric pressure.

21. The module according to claim 18, wherein the polymer film is formed by at least one thin layer comprising a polymer matrix.

22. The module according to claim 21, wherein nanoparticles of at least one metal oxide are dispersed in said matrix.

23. The module according to claim 22, wherein the metal oxide is selected from the group consisting of titanium oxide and zirconium oxide.

24. The module according to claim 21, wherein particles of at least one rare earth are dispersed in said matrix.

25. The module according to claim 18, wherein the polymer matrix is formed by at least one polyacrylic polymer or by at least one polyurethane polymer.

26. The module according to claim 25, wherein the polymer matrix is a mixture of polyacrylate polymers or copolymers containing at least 50% of an acrylic monomer of general formula CR₁R₂ in which the radical R₁ is hydrogen or a methyl group and the radical R₂ is hydrogen or a saturated hydro-carbonaceous chain comprising between 1 and 30 atoms of carbon.

27. The module according to claim 18, wherein at least a part of the inner face of the back plate is coated by an additional polymer film.

28. A process for manufacturing a module according to claim 18, wherein the polymer film is deposited on said part of the inner face of the front plate before the photovoltaic cells and peripheral seal are assembled between the front and back plates, said polymer film being in a state in which it presents adhesive properties to keep the photovoltaic cells against the front plate during assembly.

29. The process according to claim 28, wherein deposition of said polymer film is performed at a temperature of about 40° C. and the dynamic viscosity of said film is comprised between about 10³ PI and about 5*10³ PI at 40° C.

30. The process according to claim 28, wherein assembly of the photovoltaic cells and of the seal is performed at ambient temperature, the dynamic viscosity of the polymer film being comprised between about 2*10³ PI and about 10⁴ PI at ambient temperature.

31. The process according to claim 28, wherein the polymer film deposited on said part of the inner face of the front plate is cross-linkable.

32. The process according to claim 31, wherein the polymer film is cross-linked, after the photovoltaic cells and seal have been assembled, by exposing said film to ultraviolet radiation through said front plate.

33. The process according to claim 31, wherein during assembly of the photovoltaic cells and seal between the front and back plates, the polymer film is cross-linked after the photovoltaic cells have been brought into contact with the polymer film by exposing the parts of said film not covered by the photovoltaic cells directly to ultraviolet radiation.

34. The process according to claim 28, wherein an additional polymer film is deposited on at least a part of the inner face of the back plate and cross-linked before assembly.
